(19) United States
(12) Patent Application Publication
(10) Pub. No.: US 2007/0023886 A1
(43) Pub. Date: Feb. 1, 2007

(54) METHOD FOR PRODUCING A CHIP ARRANGEMENT, A CHIP ARRANGEMENT AND A MULTICHIP DEVICE

(76) Inventors: Harry Hedler, Germering (DE); Roland Irsigler, Munich (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/428,754

(22) Filed: Jul. 5, 2006

(30) Foreign Application Priority Data
Jul. 28, 2005 (DE) 102005035393.2-33

(51) Int. Cl. H01L 23/02; H01L 21/00

(52) U.S. Cl. 257/686; 438/109; 257/698; 257/700; 257/737; 438/613; 257/E23.085

(57) ABSTRACT

The present invention relates to a method and apparatus for producing a chip arrangement. In one embodiment, the method includes providing a first chip having an electrically operable structure, of providing at least one through-via through the first chip, and of arranging at least one bond wire through the through-via in the first chip.

### CROSS-REFERENCE TO RELATED APPLICATIONS

This application claims foreign priority benefits under 35 U.S.C. §119 to co-pending German patent application number DE 10 2005 035 393.2-33, filed 28 Jul. 2005. This related patent application is herein incorporated by reference in its entirety.

### BACKGROUND OF THE INVENTION

1. Field of the Invention

The present invention relates to a method for producing a chip arrangement, and for producing a multichip device as well as a chip arrangement and a multichip device.

2. Description of the Related Art

Chips are usually encapsulated in packages to protect them from environmental influences which can effect the operation of the chip or can damage them. The chips encapsulated therein are connected to contact elements provided on the package so that the chips can be contacted externally. The connecting of the chips to the contact elements is commonly carried out by wiring the contact elements to contact pads on the chips by means of bond wires attached by a conventional wire-bond technology. The wiring is usually carried out between the contact pads arranged on the chip to further contact pads on a substrate or on a redistribution layer, wherein the bond wire is led over the edges of the chips.

With increasing clock frequencies, the length of the bond wire becomes more and more an issue as it results in an increasing of the parasitic characteristics of the bond wire such as the resistance R, the inductivity L and the capacity C which exceeds an acceptable limit when high-frequency-signals are to be transferred thereby.

For this reason, through-silicon interconnect technologies have been developed. These technologies all provide a shortening of the connection length by providing an electrical interconnection through the chip. To produce such a through-via interconnection, a lot of processes are available which usually involve complex processes such as deposition technologies, i.e. DRIE, sputtering, PECVD, electro-plating, etc. Furthermore, in a multichip device having stacked chips, the electrical interconnection between the chips usually involves the applying of a high temperature and/or a high pressure, e.g. CU-to-CU-bonding. As temperatures above 180° C. have an impact on the functionality of the chip, the overall yield of the manufacturing of the packaged devices decreases.

In particular, the processes for passivating of the through-via interconnections in the chip by means of CVD and PECVD, spin-on and other processes as well as the following metallization and filling of the through-via with a conductive material by means of CVD and MOCVD processes have negative effects on the functionality of the integrated circuits of the chip as these processes are applied at a higher temperature of more than 150° C.

### SUMMARY OF THE INVENTION

According to an embodiment of the present invention, a method for producing a chip arrangement is provided. The method comprises the steps of providing a first chip having an electrically operable structure, of providing at least one through-via through the first chip, and of arranging at least one bond wire through the through-via in the first chip.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a chip arrangement including a chip according to a first embodiment of the present invention;

FIG. 2 shows a multichip device according to a further embodiment of the present invention;

FIGS. 3A and 3B show top-views on the contact area which are contacted with bondwires;

FIG. 4 shows a multichip device according to a further embodiment of the present invention;

FIG. 5 shows a multichip device according to a further embodiment of the present invention;

FIG. 6 shows a multichip device according to a further embodiment of the present invention; and

FIG. 7 shows a further embodiment of the present invention.

### DETAILED DESCRIPTION OF THE PREFERRED EMBODIMENT

One embodiment of the present invention provides a method for producing a chip arrangement and a multichip device and a chip arrangement and a multichip device, wherein the parasitic characteristics of the interconnections between the integrated circuits on the chip and external connections can be reduced and wherein the processes necessary for producing the chip arrangement and the multichip device are such that the have a reduced negative impact on the integrated circuits on the chip.

It is advantageous that an interconnection can be provided through a through-via and a chip so that the parasitic characteristics of the interconnection with regard to the conventional wirebond technology in which the chips are contacted over an edge of the chip are reduced due to the shortened length of the bond wire. Furthermore, the provision of the interconnection through the through-via can be carried out without employing a process which essentially effects the functionality of the integrated circuits in the chip in a negative manner as merely a bonding process at non-elevated temperatures is carried out. Furthermore, it is advantageous that a complex processing can be avoided after the chip is applied, thereby minimizing production costs due to an increased yield. For example, a passivating process, e.g. a PECVD process, a spin-on process and the like can be avoided. Additionally, a filling of the through-via with a conductive material by means of, e.g., a sputter or electro-plating process can be omitted. Consequently, integrated circuits on the chip may be affected or damaged by processes regarding the passivating and the filling of the through-via. In contrast thereto, according to the present invention it is provided to carry out a bonding through the through-via in the chip so that the bond wire is led through the through-via in the chip. Thereby, a contacting of the integrated circuit on the chip can be carried out by means of a shortened interconnection length of the bond wire.

Furthermore, the through-via may be produced by at least one of the following processes: drilling, powder blasting, laser drilling, chemical wet etching, chemical dry etching, and photo induced electrochemical etching, and combinations thereof.

Moreover, after providing the bond wire an isolation material is introduced in at least the through-via.

According to another embodiment, the chip has a first surface and a second surface opposite to the first surface, wherein a contact area on the first surface is provided in a region of the through-via for contacting of the electrically operable structure, wherein the bond wire is connected with the contact area on the first chip.

Furthermore, the through-via may be fully or partially located within the contact area. Alternatively, the through-via is located beyond the contact area.

According to a further embodiment of the present invention, a method for producing a chip arrangement is provided comprising the steps of providing a first chip having an electrically operable structure; of providing at least one through-via through the first chip; of arranging the first chip on a surface having a further contact area such that the further contact area is accessible via the through-via of the first chip; and of arranging at least one bond wire through the through-via in the first chip, wherein the bond wire is further connected with the further contact area.

Moreover, a contact element is provided which protrudes away from the surface and providing the further contact area at an end opposite to the surface, wherein the first chip is placed on the surface such that the contact element protrudes into the through-via, wherein the bond wire is connected with the contact area of the contact element.

Furthermore, the contact element may be arranged by one of providing a stud bump onto the further contact area by means of one of electroplating, wire bonding and attaching a preproduced stud bump, and of providing a non-conductive bump on which a conductive layer is applied.

Moreover, the first chip may have a first surface and a second surface opposite to the first surface, wherein a contact area on the first surface is provided in a region of the through-via for contacting of the electrically operable structure, wherein the bond wire is connected with the contact area on the first chip.

The through-via may be fully or partially located within the contact area. Alternatively, the through-via may be located beyond the contact area.

Moreover, between the first chip and the surface a coupling element may be arranged.

The second surface of the first chip may be arranged on a surface of a carrier substrate on which the further contact area is provided.

The second surface of the first chip may be arranged on a surface of a second chip on which the further contact area is located.

According to a further embodiment of the present invention, a method for producing a chip arrangement comprises the steps of providing a first chip and a second chip each having an electrically operable structure, wherein the first and the second chips each have a first surface and a second surface opposite to the first surface; of providing at least one through-via through the first chip; of providing at least one through-via through the second chip; of arranging the first chip on the first surface of the second chip having a further contact area such that the further contact area is accessible via the through-via of the first chip; of arranging at least one first bond wire through the through-via in the first chip, wherein the first bond wire is connected with the further contact area, wherein the further contact area on the first surface on the second chip is provided in a region of the through-via of the second chip; and of arranging at least one second bond wire through the through-via of the second chip, wherein the second bond wire is connected with the further contact area.

Furthermore, a contact element may be provided which protrudes away from the surface and provides the further contact area at an end opposite to the surface, wherein the first chip is placed on the surface such that the contact element protrudes into the through-via, and wherein the bond wire is connected with the contact area of the contact element.

Moreover, the contact element may be arranged by one of providing a stud bump onto the further contact area by means of one of electroplating, wire bonding and attaching a preproduced stud bump, and providing a non-conductive bump on which a conductive layer is applied.

A contact area on the first surface of the first chip may be provided in a region of the through-via for contacting of the electrically operable structure, wherein the first bond wire is connected with the contact area on the first chip.

The through-via of the second chip may be fully or partially located within the further contact area. Alternatively, the through-via of the second chip may be located beyond the further contact area.

Between the first chip and the first surface of the second chip a coupling element may be arranged.

Furthermore, a contact structure on the second surface of the first chip may be coupled with a further contact structure by means of a further contact element to drive the electrically operable structure.

According to a further embodiment of the present invention, a method for producing a chip arrangement comprises the steps of providing a first and a third chip each have an electrically operable structure, wherein the first and the third chips each having a first surface and a second surface opposite to the respective first surface; of providing at least one through-via through the first chip; of placing the second surface of the third chip on the first surface of the first chip, wherein, on the second surface of the third chip, a third contact area is provided which is accessible through the through-via of the first chip; and of arranging at least one bond wire through the through-via in the first chip, wherein the bond wire is coupled with the third contact area.

Between the first surface of the first chip and the second surface of the third chip a second contact element may be provided by means of which the electrically operable structure of the first and third chips are interconnected.

The through-via may be produced by at least one of the following processes: drilling, powder blasting, laser drilling, chemical wet etching, chemical dry etching, and photo-induced electrochemical etching, and combinations thereof.

After providing the bond wire, an isolation material may be introduced in at least the through-via.

The second surface of the first chip may be arranged on a surface of a carrier substrate on which the further contact area is provided.

The second surface of the first chip may be arranged on a surface of a second chip on which the further contact area is located.

According to a further embodiment of the present invention, a method for producing a chip arrangement comprises the steps of providing a first chip having an electrically operable structure; of providing at least one through-via through the first chip; of arranging a contact element on a surface such that the contact element protrudes from the surface; of arranging the first chip on the surface, wherein the contact element protrudes from the surface into the through-via of the first chip; and of arranging at least one bond wire through the through-via in the first chip, wherein the bond wire is connected with the contact element.

According to an embodiment of the present invention, the contact element is arranged by one of providing a stud bump onto the further contact area by means of one of electroplating, wirebonding and attaching a preproduced stud bump, and of providing a non-conductive bump on which a conductive layer is applied.

Furthermore, the chip may have a first surface and a second surface opposite to the first surface, wherein a contact area on the first surface is provided in a region of the through-via for contacting of the electrically operable structure, wherein the bond wire is connected with the contact area on the first chip.

Furthermore, the second surface of the first chip may be arranged on a surface of a second chip on which the contact element is located.

According to a further embodiment of the present invention, a chip arrangement is provided comprising a chip with an electrically operable structure, a through-via which is provided in the chip, and a bond wire which is located within the through-via of the chip.

Furthermore, in the through-via an isolating material may be introduced.

A contact area on the first surface of the chip may be provided in a region close to the through-via to contact the electrically operable structure, wherein the bond wire is coupled with the contact area. In particular, the through-via may be located within the contact area.

Moreover, the first chip may be arranged on a surface having a further contact area so that the further contact area is accessible via the through-via, wherein the further contact area and the contact area are interconnected by means of the bond wire through the through-via of the chip.

A contact element may be provided which protrudes away from the surface and provides the further contact area at an end opposite to the surface, wherein the first chip is placed on the surface such that the contact element protrudes into the through-via, wherein the bond wire is connected with the contact area of the contact element.

The contact element may comprise one of a stud bump and a non-conductive bump on which a conductive layer is applied.

Between the chip and the surface a connection element may be provided.

Furthermore, the chip may be arranged on a surface of a carrier substrate, on which the further contact area is located.

The carrier substrate may further comprise a through-channel in the region of the through-via of the first chip, wherein the bond wire extends through the through-channel of the carrier substrate.

According to a further embodiment of the present invention, a multichip device is provided having a first chip and a second chip wherein the first and the second chip each comprise an electrically operable structure, a first surface and a second surface opposite to the first surface, wherein the first chip is arranged on the first surface of the second chip, wherein at least one through-via is provided in one of the first and second chips, wherein at least one bond wire is provided in the at least one through-via.

The through-via may be provided in the first chip, wherein a contact area is provided on the first surface of the first chip in a region of the through-via for contacting the electrically operable structure, wherein the bond wire is connected with the contact area on the first chip.

A further contact area may be located on the first surface of the second chip, wherein the bond wire is connected with the further contact area of the second chip.

A through-via may be provided in the second chip, through which a further bond wire extends which is coupled with the further contact area of the second chip.

According to a further embodiment of the present invention, a multichip device has a first chip and a third chip wherein the first and the third chip each comprise an electrically operable structure, a first surface and a second surface opposite to the first surface, wherein the third chip is arranged on the first surface of the first chip, wherein a through-via is provided in the first chip; wherein a bond wire is provided in the through-via of the first chip, wherein a third contact area is arranged on the second surface of the third chip so that the third contact area is accessible through the through-via of the first chip, wherein the bond wire is coupled with the third contact area.

Between the first surface of the first chip and second surface of the third chip a coupling element may be provided.

According to a further embodiment of the present invention, a multichip device is provided comprising a first chip and a second chip each having an electrically operable structure, wherein the first and the second chips each have a first surface and a second surface opposite to the first surface; at least one through-via through the first chip; at least one through-via through the second chip, wherein the first chip is arranged on the first surface of the second chip which has a further contact area such that the further contact area is accessible via the through-via of the first chip; wherein at least one first bond wire is arranged through the through-via in the first chip, wherein the first bond wire is connected with the further contact area, wherein the further contact area on the first surface on the second chip is provided in a region of the through-via of the second chip, and wherein at least one second bond wire is arranged through the through-via of the second chip, wherein the second bond wire is connected with the further contact area.

A contact element may be provided which protrudes away from the first surface of the second chip and provides the further contact area at its end opposite to the first surface, wherein the first chip is placed on the first surface of the second chip so that the contact element protrudes into the through-via, wherein the bond wire is connected with the contact area of the contact element.

A contact area on the first surface of the first chip may be provided in a region of the through-via for contacting of the electrically operable structure, wherein the first bond wire is connected with the contact area on the first chip.

The through-via of the second chip may be fully or partially located within the further contact area. Alternatively, the through-via of the second chip may be located beyond the further contact area.

Between the first chip and the first surface of the second chip a coupling element may be arranged.

A contact structure on the second surface of the first chip may be coupled with a further contact structure by means of a further contact element to drive the electrically operable structure.

According to a further embodiment of the present invention, a chip arrangement comprises a first chip having an electrically operable structure; wherein the first chip has a first surface and a second surface opposite to the first surface, wherein at least one through-via is provided through the first chip; a contact element arranged on a surface wherein the contact element protrudes from the surface; wherein the first chip is arranged on the surface with its second surface, wherein the contact element protrudes from the surface into the through-via of the first chip; and at least one bond wire extending through the through-via in the first chip, wherein the bond wire is connected with the contact element.

In one embodiment, the contact element comprises one of a conductive stud bump and a non-conductive bump on which a conductive layer may be applied.

A contact area on the first surface of the first chip may be provided in a region of the through-via for contacting of the electrically operable structure, wherein the bond wire is connected with the contact area on the first chip.

Furthermore, the second surface of the first chip may be arranged on a surface of a carrier substrate on which the contact element is provided.

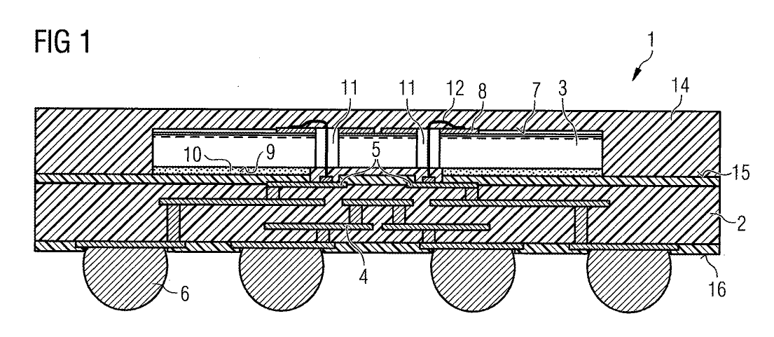

In FIG. 1 a chip arrangement, also referred to as a device 1 is illustrated, having a substrate 2 and a chip 3 attached thereon. To protect the chip 3 against environmental influences the chip 3 is encapsulated by an encapsulation material 14 so that the encapsulation material 14 and the substrate 2 fully enclose the chip 3 and form the device 1 in a package. The chip 3 may be of any size. It is understood that a chip, as referred to herein, may be a semi-conductor substrate having an integrated circuit arranged therein and/or thereon and other substrates, wherein electronics circuits and/or electromechanical structures are included. A chip as used herein is also referred to as an electrically operable structure. Furthermore, the term “chip” may be understood as including a number of chips such as a wafer.

The substrate 2 includes a redistribution structure 4 which is adapted to connect first contact areas 5 on a first surface 15 of the substrate 2 with contact elements 6 on a second surface 16 of the substrate 2 opposite to the first surface 15. The contact elements 6 are e.g. designed as solder balls by means of which the device can be connected to (soldered on) a printed circuit board (in case the device is of a ball-grid-array-type). The chip 3 comprises a first surface 7 on which electrically operable structures are integrated such as an integrated circuit and the like and on which second contact areas 8 are arranged which can be contacted.

Opposite to the first surface 7 of the chip 3 a second surface 9 is arranged. The chip 3 is arranged on the first surface 15 of the substrate 2 with its second surface 9. To mount the chip 3 on the first surface 15 of the substrate 2, a coupling element 10, for example as an adhesive layer, can be provided to mount chip 3 on the first surface 15 of the substrate 2. Thereby, a chip 3 can be fixed to prevent a lateral removing of the chip 3 with regard to the first surface 15 which might result in a shearing of the bond wire 12. The coupling element 10 may be dispensed as an adhesive layer, wherein in particular in the region in which the first contact area 5 is located should not be covered by the adhesive layer to allow a free contact ability of the first contact area 5.

Chip 3 includes a through-via 11 extending from the first surface 7 to a second opposing surface 9. Chip 3 is arranged on the first surface 15 of the substrate 2 such that at least one of the first contact areas 5 on the first surface 15 of the substrate 2 is accessible through the through-via 11. One of the second contact areas 8 is connected with the first contact area 5 by means of a bond wire 12 so that the second contact area 8 can be electrically coupled with a contact element 6 which is connected with the first contact area 5 via a respective rewiring structure 4. Thereby, the integrated circuit on the first surface of the chip 3 can be contacted via the respective contact element 6. The term “bond wire” as used herein refers to a wire shaped conductor which is mounted on at least one contact pad by means of bonding equipment and using a wirebond technology to provide an electrical connection.

The through-via 11 in the chip 3 may be produced by at least one of the processes drilling, laser drilling, etching and the like, for example by means of a suitable process by which the electrically operable structures on the first surface of chip 3 are not impacted in functionality.

The through-via 11 may comprise a cross-section having a size which allows a bonding equipment to be positioned so that a bond wire 12 can be led through the through-via 11 and bonded to the first contact area 5 on the first surface 15 of the substrate 2. The bond wire 12 is further bonded to the second contact area 8 which is arranged on the first surface 7 of the chip 3 and close to the respective through-via 11, and may abut on the opening of the respective through-via 11 on the first surface 7 of the chip 3. The through-via 11 may be filled after the bonding by means of an insulating material or an insulating element so that the bond wire 12 is protected against a bending and no shorts between the bond wire 12 and the substrate of the chip 3 can occur. The insulation material may be dispensed as a liquid on the through-via 11 by means of a dispense capillary so that the insulation means flows into the through-via 11 by the capillary effect.

In one embodiment, the first and second contact areas 5, 8 are selected so that the bonding equipment may reliably be positioned on the respective contact areas 5, 8 and attached the bond wire 12 thereon. By means of conventional bonding equipment through-vias 11 having a diameter in a range from 40 μm to 80 μm can be positioned and can be bonded through a through-via 11 if the thickness of the chip 3 is selected to be as low as in a range of 60 μm to 150 μm, preferably at about 70 μm. However also a lower or higher thickness may be selected, depending on the performance of the respective bonding equipment related to the place and route capability.

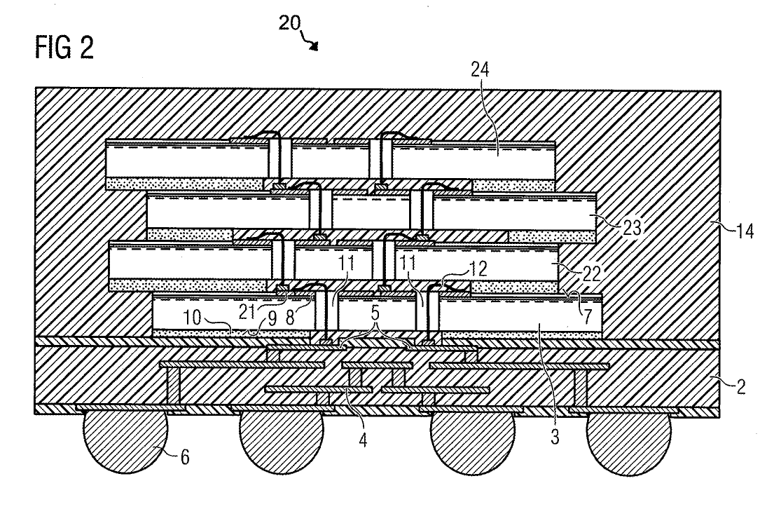

In FIG. 2, a multichip device 20 according to a further embodiment of the present invention is illustrated. Elements with the same or similar functionality are indicated by the same reference signs as already used in FIG. 1. The multichip device 20 includes, besides the first chip 3 a second, third and fourth chip 22, 23 and 24, which are stacked onto one another. The respective first surface 7 of the second, third and fourth chip 22, 23, 24 are directed in the same direction as the first surface 7 of the first chip 3. On the first surface 7 of the first chip 3 the second chip 22 is arranged, which also has through-vias 11 and comprises respective second contact areas 8 on its first surface 7. On the first surface 7 of the second chip 22 the third chip 23 is arranged on the first surface 7 of which the fourth chip 24 is placed. The third chip 23 as well as the fourth chip 24 comprise respective through-vias 11 and respective second contact areas 8. The second chip 22 is placed on the first chip 3 so that the respective through-vias 11 of the second chip 22 are adjusted to corresponding further second contact areas 21 of the first surface 7 of the first chip 3 which are either electrically connected with the integrated circuit of the first chip 3 or with the second contact areas 8 which are coupled with the bond wires 12. The further second contact areas 21 of the first chip 3 are connected with the respective second contact areas 8 on the first surface of the second chip 22 by means of bond wires 12 through the through-vias 11 of the second chip 22, correspondingly.

In one embodiment, to fix the second chip 22 on the first surface of the first chip 3, an adhesive layer 10 is provided which is applied to the first surface 7 of the first chip 3 without covering the second contact areas 8. Subsequently the second chip 22 is placed in an adjusted manner so that the respective through-vias 11 are adjusted onto the second contact areas 8 which are provided for connecting of the second chip 22. Thereafter, a bonding is carried out, wherein the further second contact areas 21 of the first chip 3 are interconnected with the respective associated second contact areas 8 of the second chip 22 by means of bond wires 12.

In a similar manner like the second chip 22, the third chip 23 and the fourth chip 24 are placed on the first surface 7 of the second and the third chips 23, 24, respectively. To connect one of the further second contact areas 21 on the second, third or fourth chip 22, 23, 24 with one of the first contact areas 5 on the first surface of the substrate 2, the second contact areas 8 on the chips between the respective chip and the first surface of the substrate 2 are formed as a common second contact area having an enlarged area which then included the second contact area 8 and the further second contact area 21. On the common second contact area then the bond wire 12 through the through-via 11 of the chip on which the common second contact area is located and the bond wire 12 through the through-via 11 of the chip arranged thereon are connected with the common contact area. The second contact area may be formed so that it surrounds the area of the through-via 11 of the respective chip as well as the region of the through-via 11 of the chip arranged thereon, i.e. such that the respective through-via 11 is located in the region of the second contact area.

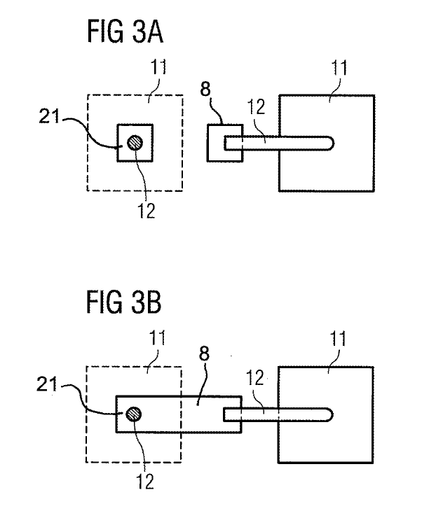

According to another embodiment a second contact area 8, 21 can be arranged besides the opening of the through-via 11 on the respective surface for bonding. This is illustrated in FIG. 3A as an example, wherein a top-view on the first surface 7 of the respective chip is shown. It can be seen that the bond wire 12 is led through the through-via 11 of the respective chip 3, 22, 23, 24 and which is bonded to the second contact area 8 which is located close to the through-via 11, substantially at a location between the through-via 11 and the region of the opening of through-via 11 of the chip arranged thereon wherein the further second contact area 21 is located. Through the through-via 11 of the upper chip the further second contact area 21 is contacted by means of the respective bond wire 12 which itself is connected with one of the second contact areas of the first surface 7 of the respective chip 22, 23, 24 arranged thereon. As shown in FIG. 3B, the second contact area 8 and the further second contact area 21 can be provided as the common second contact area.

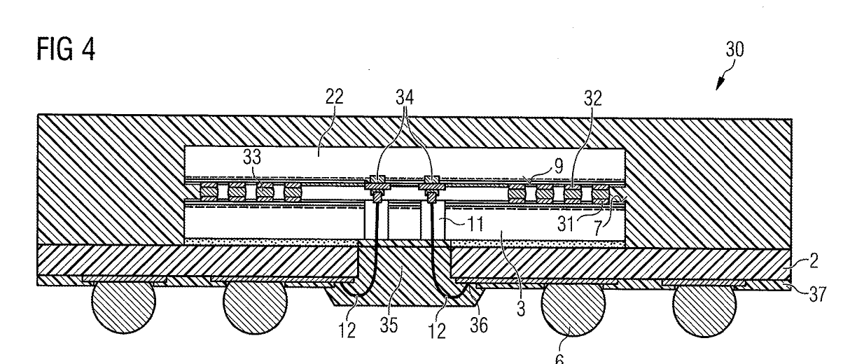

With regard to FIG. 4 a further embodiment of the multichip device 30 is shown. On the substrate 2 a first chip 3 is arranged which comprises the through-vias 11. On the first surface 7 of the first chip 3 first contact areas 31 are located by means of which integrated circuits of the chip 3 can be electrically connected. On the first surface 7 of the first chip 3 a second chip 22 is placed with its second surface 9. The second chip 22 comprises second contact areas 32 on its second surface 9, wherein the second contact areas 32 are substantially opposing first contact areas 31 on the first surface of the first chip 3. The first and second chips 3, 22 are interconnected by means of contact elements 33 which may be provided as solder balls, for example, and which are soldered between the first and second contact areas 31, 32 so that an electrical interconnection between the integrated circuits of both chips 3, 22 can be provided and/or at least a mechanical fixation of the second chip 22 on the first chip 3 is provided.

The second surface 9 of the second chip 22 further comprises one or more third contact elements 34 which substantially oppose the through-vias 11 in the first chip 3 so that bonding equipment can access the third contact elements 34 through the through-vias 11. The substrate 2 further comprises a through-channel 35 in which the through-vias 11 of the first chip 3 open out.

A second surface of the substrate 2 further includes fourth contact areas 36 which are interconnected with the contact elements 6 (solder balls) by means of a redistribution structure 37. The bonding then is carried out from the direction of the second surface of the substrate 2 by leading a bond wire 12 from one of the third contact areas 34 through the through-via 11 to the associated fourth contact area 36, respectively. Thereby, it is possible to reduce the length of the bond wires 12 for contacting of the second chip 22 via the contact elements 6.

The second chip 22 may be provided as a flip-chip device, wherein the integrated circuit is integrated in or on the second surface 9. Thereby, it can be avoided to provide through-vias in the second chip 22 so that chip area can be saved.

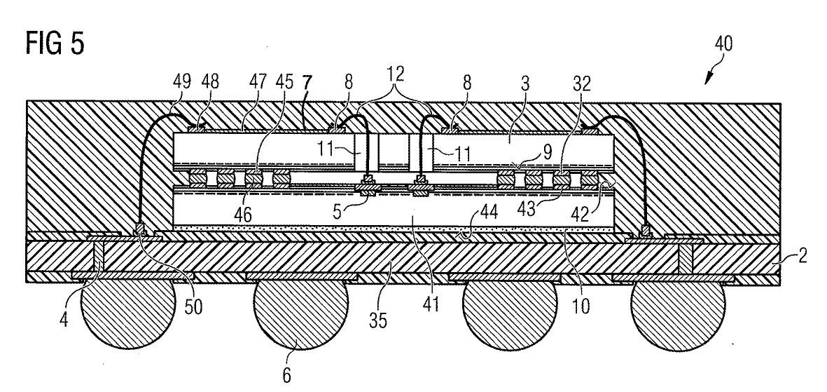

In a further embodiment shown in FIG. 5, a multi-chip device 40 according to the present invention is shown. In this embodiment the first chip 3 is placed on a first surface 42 of a fifth chip 41. The fifth chip 41 is placed on the first surface of the substrate 2 with its second surface 44 by means of a suitable coupling element 10 as mentioned before. On the first surface 42 of the fifth chip 41 first contact elements 5 are arranged. The first chip 3 includes through-vias 11 which are arranged above the first contact elements 5, so that the first contact elements 5 are accessible through the through-vias 11. The second surface 9 of the first chip 3 further comprises second contact areas 45 which oppose first contact areas 43 of the fifth chip 41 and which are connected to them via contact elements 46, which may be provided as solder balls and the like. An integrated circuit may be provided in the second surface 9 of the first chip 3 in this embodiment.

On the first surface 7 of the first chip 3, second contact elements 8 are placed which are interconnected with the first contact elements 5 through the corresponding through-via 11 by means of a bond wire 12. The further contact areas 8 may be connected to a fifth contact area 48 by means of a further redistribution structure 47 which is connected to a sixth contact area 50 by means of a further bond wire 49. The sixth contact area 50 is on the first surface of the substrate 2 and may be connected to the contact elements 6 on the second surface of the substrate 2 via the redistribution structure 4.

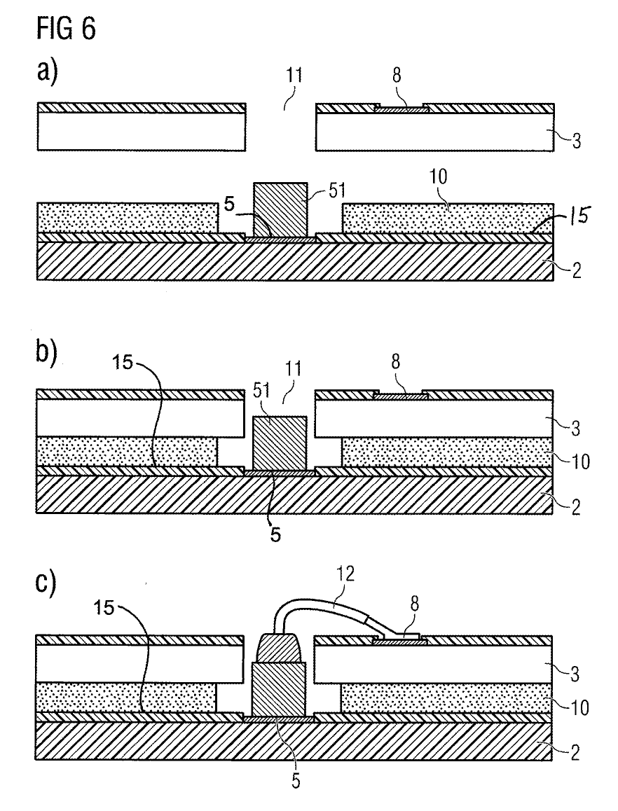

As shown in the embodiment of FIG. 6 wherein the stages for producing a chip arrangement having one chip on the substrate 2 is depicted in FIGS. 6a to 6c, the first contact area 5 on the first surface 15 of the substrate 2 as well as the second contact area 8 of one of the chips in the embodiments of FIG. 2, 4 and 5 can be provided in an elevated manner. The first and second contact areas 5, 8, respectively, can thereby be provided an elevated contact area 51 which is placed on the first and/or second contact area 5, 8, respectively, with the upper end, i.e. the end of the elevated contact area 51 opposing the surface on which it is placed, such as the respective contact area. The elevated contact area 51, also referred to as a contact element can be produced by wirebonding a stud-bump or stacking a number of wirebonded stud-bumps. The contact element is designed so that while placing a respective chip having a through-via 11, the contact elements protrudes from the first surface of the substrate 15 or the respective chip 3 into the through-via 11 of the chip arranged thereon. After placing the respective chip a bonding is carried out. When the contact area is elevated from the first surface the length of the bond wire 12 is further reduced, and placing and routing of the bonding equipment to position the bond wire is facilitated. The stud-bump furthermore can be provided on the first surface of the substrate 2 and/or one of the chips arranged thereon by means of electro-plating or electroless-plating. Furthermore, the stud-bump may be provided as a non-conducting elevation on the first surface which is covered with a conductive layer on which the bond wire can be bonded by means of a bonding process.

According to a further embodiment it is possible to separately provide a stud-bump and to place the provided stud-bump by means of a pick-and-place-tool on the first surface either of the substrate or of the respective chip and fixate it. Substantially, the material of the stud-bump may be any conductive material such as gold, copper and the like. However, it is preferred to use a material on which a bond wire can be easily bonded by means of a bonding process.

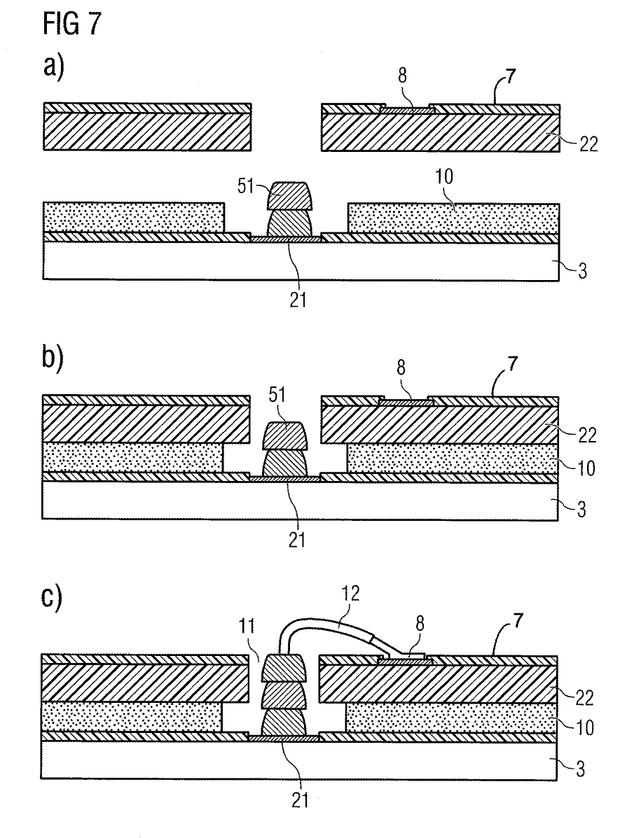

As shown in FIG. 7 wherein the stages for producing a chip arrangement for a multichip device is depicted in FIGS. 7a to 7c, a stacking of the first and the second chips 3, 22 is illustrated wherein FIG. 7a shows the stage before the stacking of the chips, FIG. 7b the stage after stacking and before bonding and FIG. 7c the stage after bonding of the chip through the through-via 11. To increase the height of the stud-bump 51, the attachment of a bondwired stud-bump can be performed a number of times such that the stud-bump 51 is formed by a number of bond wire bumps, which are stacked onto one another. The height of the stud-bump 51 provided thereby may be such that the first surface 7 of the chip 22 in the through-via 11 of which the stud-bump 51 is introduced is higher, equal or lower than the upper end of the stud-bump.

While the foregoing is directed to embodiments of the present invention, other and further embodiments of the invention may be devised without departing from the basic scope thereof, and the scope thereof is determined by the claims that follow.

What is claimed is:

1. A method for producing a chip arrangement comprising:
providing a first chip having an electrically operable structure;
providing at least one through-via through the first chip; and
arranging at least one bond wire through the through-via in the first chip.

2. The method of claim 1, wherein the through-via is produced by at least one of drilling, powder blasting, laser drilling, chemical wet etching, chemical dry etching, photo-induced electrochemical etching and combinations thereof.

3. The method of claim 1, further comprising:
after providing the bond wire, introducing an isolation material in at least the through-via.

4. The method of claim 1, wherein the chip has a first surface and a second surface opposite the first surface, wherein a contact area on the first surface is provided in a region of the through-via for contacting of the electrically operable structure, and wherein the bond wire is connected with the contact area on the first chip.

5. The method of claim 4, wherein the through-via is located within the contact area.

6. The method of claim 4, wherein the through-via is located outside of the contact area.

7. A method for producing a chip arrangement comprising:
providing a first chip having an electrically operable structure;
providing at least one through-via through the first chip;
arranging the first chip on a surface having a first contact area such that the first contact area is accessible via the through-via of the first chip; and
arranging at least one bond wire through the through-via in the first chip, wherein the bond wire is connected with the first contact area.

8. The method of claim 7, further comprising:
providing a contact element which protrudes away from the surface; and
providing the first contact area at an end opposite to the surface, wherein the first chip is placed on the surface such that the contact element protrudes into the through-via, wherein the bond wire is connected with the contact area of the contact element.

9. The method of claim 8, wherein the contact element is arranged by one of providing a stud bump onto the first contact area by one of electroplating, wirebonding and attaching a preproduced stud bump, and providing a non-conductive bump on which a conductive layer is applied.

10. The method of claim 7, wherein the first chip has a first surface and a second surface opposite to the first surface, wherein a contact area on the first surface is provided in a region of the through-via for contacting of the electrically operable structure, wherein the bond wire is connected with the contact area on the first chip.

11. The method of claim 10, wherein a coupling element is arranged between the first chip and the surface.

12. The method of claim 10, wherein the second surface of the first chip is arranged on a surface of a carrier substrate on which the first contact area is provided.

13. The method of claim 7, wherein the second surface of the first chip is arranged on a surface of a second chip on which the first contact area is located.

14. A method for producing a chip arrangement, comprising:
providing a first chip and a second chip each having an electrically operable structure, wherein the first and the second chips each having a first surface and a second surface opposite to the first surface;
providing at least one through-via through the first chip;
providing at least one through-via through the second chip;
arranging the first chip on the first surface of the second chip having a first contact area such that the first contact area is accessible via the through-via of the first chip;
arranging at least one first bond wire through the through-via in the first chip, wherein the first bond wire is connected with the first contact area, wherein the first contact area on the first surface on the second chip is provided in a region of the through-via of the second chip; and
arranging at least one second bond wire through the through-via of the second chip, wherein the second bond wire is connected with the first contact area.

15. A chip arrangement comprising:
a chip with an electrically operable structure,
a through-via which is provided in the chip, and
a bond wire which is located within the through-via of the chip.

16. The chip arrangement of claim 15, wherein an isolating material is introduced in the through-via.

17. The chip arrangement including of claim 15, wherein a contact area on the first surface of the chip is provided in a region close to the through-via to contact the electrically operable structure, wherein the bond wire is coupled with the contact area.

18. The chip arrangement of claim 17, wherein the through-via is located within the contact area.

19. The chip arrangement of claim 17, wherein the first chip is arranged on a surface having a first contact area so that the first contact area is accessible via the through-via, wherein the first contact area and the contact area are interconnected by means of the bond wire through the through-via of the chip.

20. The chip arrangement of claim 19, wherein a contact element protrudes away from the surface and wherein the first contact area is provided at an end opposite to the surface, wherein the first chip is placed on the surface such that the contact element protrudes into the through-via, wherein the bond wire is connected with the contact area of the contact element.

21. The chip arrangement of claim 20, wherein the contact element comprises one of a stud bump and a non-conductive bump on which a conductive layer is applied.

22. The chip arrangement of claim 19, wherein the chip is arranged on a surface of a carrier substrate, on which the first contact area is located.

23. The chip arrangement of claim 22, wherein the carrier substrate comprises a through channel in the region of the through-via of the first chip, wherein the bond wire extends through the through channel of the carrier substrate.

24. A multichip device having a first chip and a second chip wherein the first and the second chip each comprise an electrically operable structure, a first surface and a second surface opposite to the first surface, wherein the first chip is arranged on the first surface of the second chip, wherein at least one through-via is provided in one of the first and second chips; wherein at least one bond wire is provided in the at least one through-via.

25. The multichip device of claim 24, wherein the through-via is provided in the first chip, wherein a contact area is provided on the first surface of the first chip in a region of the through-via for contacting of the electrically operable structure, wherein the bond wire is connected with the contact area on the first chip.

26. The multichip device of claim 25, wherein a first contact area is located on the first surface of the second chip, wherein the bond wire is connected with the first contact area of the second chip.

27. The multichip device of claim 25, wherein a through-via is provided in the second chip, through which a first bond wire extends which is coupled with the first contact area of the second chip.

28. A chip arrangement comprising:
a first chip having an electrically operable structure; wherein the first chip has a first surface and a second surface opposite to the first surface, wherein at least one through-via is provided through the first chip;
a contact element arranged on a surface wherein the contact element protrudes from the surface, wherein the first chip is arranged on the surface with its second surface, and wherein the contact element protrudes from the surface into the through-via of the first chip; and
at least one bond wire extending through the through-via in the first chip, wherein the bond wire is connected with the contact element.

29. The chip arrangement of claim 28, wherein the contact element comprises one of a conductive stud bump and a non-conductive bump on which a conductive layer is applied.
